(19) United States
(12) Patent Application Publication
(10) Pub. No.: US 2022/0399211 A1
(43) Pub. Date: Dec. 15, 2022

(54) APPARATUS, SYSTEM, AND METHOD FOR DRYING SEMICONDUCTOR WAFERS

(71) Applicant: Akrion Technologies Inc., Allentown, PA (US)

(72) Inventor: Ryan Gregory, Fleetwood, PA (US)

(21) Appl. No.: 17/829,530

(22) Filed: Jun. 1, 2022

Related U.S. Application Data
(60) Provisional application No. 63/209,642, filed on Jun. 11, 2021.

(51) Int. Cl. H01L 21/67; B08B 3/04; B08B 13/00; B25J 11/00

(52) U.S. Cl. CPC H01L 21/67034; B08B 3/04; B08B 13/00; B25J 11/0095

(57) ABSTRACT

An apparatus and method for drying semiconductor wafers. The apparatus includes a tank that holds hold a liquid, a first lifting assembly, and a second lifting assembly. The first lifting assembly lifts and lowers a first wafer carrier and one or more semiconductor wafers supported thereon between a first lowered position in which the one or more semiconductor wafers are completely submerged in the liquid in the tank and a first raised position in which an upper portion of the one or more semiconductor wafers are not submerged in the liquid in the tank. The second lifting assembly has a second wafer carrier that engages the upper portion of the one or more semiconductor wafers and continues to lift the one or more semiconductor wafers until an entirety of the one or more semiconductor wafers is no longer submerged in the liquid in the tank.

### CROSS-REFERENCE TO RELATED APPLICATIONS

The present application claims the benefit of priority to U.S. Provisional Patent Application Ser. No. 63/209,642, filed Jun. 11, 2021, the entirety of which is incorporated herein by reference.

### BACKGROUND OF THE INVENTION

Marangoni dryers have been used in the past to dry semiconductor wafers that are being processed, such as by liquid baths. Marangoni drying is based on surface tension gradient forces and is an ultra-clean drying process. In this technique, a volatile organic compound with lower surface tension than water, such as isopropyl alcohol (IPA), is introduced in the vicinity of a substrate semiconductor wafer in the form of a vapor as the substrate wafer is slowly withdrawn from a bath of water. As the small quantity of alcohol vapor comes into contact with the continuously refreshed water meniscus, it is absorbed into the water and creates a surface tension gradient. The gradient causes the meniscus to partially contract and assume an apparent finite flow angle. This causes a thin water film to flow off the substrate and leave it dry. This flow also will assist. In removing non-volatile contaminants and entrained particles.

Using current processes, a lifting mechanism raises the wafer most of the way out of the bath of water, and then a knife structure pushes the wafer from below the rest of the way out of the bath of water. The reason the knife structure is used is that it minimizes contact points on the semiconductor wafer as the wafer is being moved past the water meniscus. However, the knife is in direct physical contact with a part of the wafer as it emerges from the liquid, so there remains a water mark on the wafer at this contact point. Furthermore, because the knife is used to push the wafers up and out of the water from below, there must be slots for the wafers to fit through to maintain the wafers in their vertical orientation. Such slots may scratch the sides of the wafer during this process.

Thus, a need exists for an updated apparatus and method for drying semiconductor wafers using the Marangoni process that overcomes the noted deficiencies.

### SUMMARY OF THE INVENTION

The invention is directed to an apparatus and method for drying semiconductor wafers. The apparatus includes a tank that holds hold a liquid, a first lifting assembly, and a second lifting assembly. The first lifting assembly lifts and lowers a first wafer carrier and one or more semiconductor wafers supported thereon between a first lowered position in which the one or more semiconductor wafers are completely submerged in the liquid in the tank and a first raised position in which an upper portion of the one or more semiconductor wafers are not submerged in the liquid in the tank. The second lifting assembly has a second wafer carrier that engages the upper portion of the one or more semiconductor wafers and continues to lift the one or more semiconductor wafers until an entirety of the one or more semiconductor wafers are no longer submerged in the liquid in the tank.

In one embodiment, the invention can be an apparatus for drying semiconductor wafers, the apparatus comprising: a tank containing a liquid; a first lifting assembly comprising a first wafer carrier configured to hold one or more semiconductor wafers, the first lifting assembly being operable to move the first wafer carrier between a first lowered position wherein the one or more semiconductor wafers are completely submerged in the liquid in the tank and a first raised position wherein a lower portion of the one or more semiconductor wafers remain submerged in the liquid in the tank and an upper portion of the one or more semiconductor wafers is no longer submerged in the liquid in the tank; and a second lifting assembly comprising a second wafer carrier that is configured to: engage the upper portion of the one or more semiconductor wafers after the upper portion of the one for more semiconductor wafers has been removed from the liquid; and continue to raise the one or more semiconductor wafers until an entirety of the one or more semiconductor wafers is removed from the liquid in the tank.

In another embodiment, the invention can be a method of drying semiconductor wafers, the method comprising: supporting one or more semiconductor wafers with a first wafer carrier at one or more contact points, wherein the one or more semiconductor wafers and the first wafer carrier are completely submerged in a liquid; raising the first wafer carrier to begin lifting the one or more semiconductor wafers out of the liquid until an upper portion of the one or more semiconductor wafers is removed from the liquid and the one or more contact points remain submerged in the liquid; engaging at least a portion of the upper portion of the one or more semiconductor wafers that has been removed from the liquid with a second wafer carrier; and raising the second wafer carrier so that the second wafer carrier takes over support of the one or more semiconductor wafers, the second wafer carrier lifting the one or more semiconductor wafers until an entirety of the one or more semiconductor wafers is no longer submerged in the liquid.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein

FIG. 1 is a front perspective view of an apparatus for drying semiconductor wafers;

FIG. 2 is a rear perspective view of the apparatus of FIG. 1;

FIG. 3 is an exploded front perspective view of the apparatus of FIG. 1;

FIGS. 4A and 4B are front and perspective views respectively of a track of the apparatus of FIG. 1 that facilitates movement of a second lifting assembly thereof;

FIGS. 5 and 6 are close-up rear perspective views of the apparatus illustrating engagement between a follower member of the second lifting assembly and the track;

FIG. 7A is a rear perspective view of the apparatus of FIG. 1 with a tank thereof shown in dotted lines so that interior structures are visible, wherein a first lifting assembly is supporting a semiconductor wafer in a first lowered position;

FIG. 7B is a cross-sectional view taken along line VII-VII of FIG. 7A;

FIG. 8A is the rear perspective view of FIG. 7A with the first lifting assembly in a first raised position;

FIG. 8B is a cross-sectional view taken along line VIII-VIII of FIG. 8A;

FIG. 9A is the rear perspective view of FIG. 8A with the second lifting assembly engaging the semiconductor wafer in a second lowered position;

FIG. 9B is a cross-sectional view taken along line IX-IX of FIG. 9A;

FIG. 10A is the rear perspective view of FIG. 9A with the second lifting assembly in the second raised position; and

FIG. 10B is a cross-sectional view taken along line X-X of FIG. 10A.

### DETAILED DESCRIPTION OF THE INVENTION

The following description of the preferred embodiment(s) is merely exemplary in nature and is in no way intended to limit the invention, its application, or uses.

The description of illustrative embodiments according to principles of the present invention is intended to be read in connection with the accompanying drawings, which are to be considered part of the entire written description. In the description of the exemplary embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top,” “bottom,” “front” and “rear” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” “secured” and similar refer to a relationship wherein structures are secured or attached to one another either directly or indirectly through intervening structures, as well as both movable or rigid attachments or relationships, unless expressly described otherwise. Moreover, the features and benefits of the invention are described by reference to the exemplary embodiments illustrated herein. Accordingly, the invention expressly should not be limited to such exemplary embodiments, even if indicated as being preferred. The discussion herein describes and illustrates some possible non-limiting combinations of features that may exist alone or in other combinations of features. The scope of the invention is defined by the claims appended hereto.

For purposes of this invention, it is to be understood that the term semiconductor wafer is intended to mean any solid substance onto which a layer of another substance is applied and that is used in the solar or semiconductor industries. This includes, without limitation, silicon wafers, glass substrates, fiber optic substrates, fused quartz, fused silica, epitaxial silicon, raw wafers, solar cells, medical devices, disks and heads, flat panel displays, microelectronic masks, and other applications requiring high purity fluids for processing. The terms substrate and wafer may be used interchangeably throughout the description herein. Furthermore, it should be understood that the invention is not limited to any particular type of substrate and the methods described herein may be used for the preparation and/or drying of any flat article.

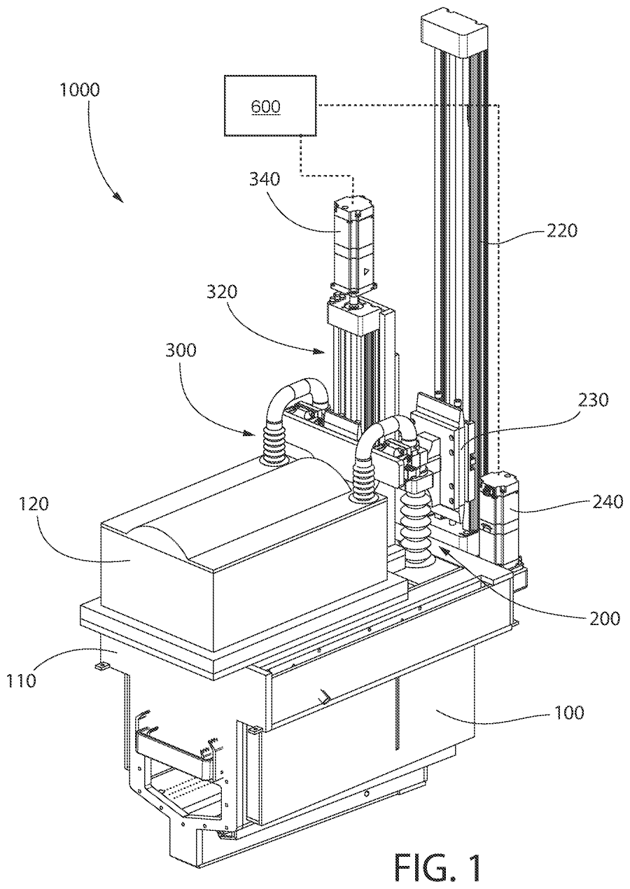

Referring first to FIGS. 1-3, an apparatus for drying semiconductor wafers (hereinafter “the apparatus”) 1000 will be described in accordance with an embodiment of the present invention. The apparatus 1000 is a Marangoni-type dryer that is used for drying semiconductor wafers after a wet processing step during the manufacture of integrated circuits and the like. In Marangoni drying, the semiconductor wafers are slowly removed from a liquid bath while isopropyl alcohol (IPA) vapor (or other volatile organic compounds (VOCs)) is introduced into the tank in the vicinity of the semiconductor wafer. The IPA vapor is more specifically introduced into the tank prior to removing the semiconductor wafer from the liquid bath to create a liquid-to-IPA vapor interface along a top surface of the bath. The liquid-to-IPA vapor interface creates a surface tension differential that encourages and forces the liquid to separate from the semiconductor wafers as the semiconductor wafers are slowly raised/lifted out of the bath. Specifically, as the small quantity of alcohol vapor comes into contact with the continuously refreshed water meniscus during removal of the semiconductor wafer, the alcohol absorbs in the water thereby creating a surface tension gradient. Thus, as the semiconductor wafer is slowly lifted out of the liquid bath, the water in the meniscus is pulled down into the bulk liquid and leaves the semiconductor surfaces completely dry such that water spots do not appear. The surface tension gradient causes the meniscus to partially contract and assume an apparent finite angle via a flow, which causes the thin water film to flow off the semiconductor wafer, leaving it dry. Liquid spots left on the semiconductor wafer surface can cause oxidation that damages components on the semiconductor wafer. Thus, it is important to dry the semiconductor wafer as thoroughly as possible, and the apparatus 1000 described herein does this effectively.

The apparatus 1000 generally comprises a tank 100, a first lifting assembly 200, and a second lifting assembly 300. The tank 100 is configured to hold a liquid within which one or more semiconductor wafers are positioned. The liquid may be deionized water in some particular embodiments. The first and second lifting assemblies 200, 300 are configured to work together to remove the one or more semiconductor wafers from the liquid in the tank 100 to dry the one or more semiconductor wafers using the Marangoni drying process, which is a process that is well known by persons of ordinary skill in the art and has been described briefly above. The first and second lifting assemblies 200 may move at a slow speed such as in a range of 0.1 mm/second to 3 mm/second, and more specifically approximately 1 mm/second (with the term “approximately” including a plus/minus of 0.2 mm/second). Isopropyl alcohol (IPA) as a vapor or gas or a mixture of IPA vapor and nitrogen gas may be introduced into the tank to form an IPA vapor barrier on the uppermost surface of the liquid in the tank. The IPA vapor may continue to be dispensed into the tank as the one or more semiconductor wafers emerge from the surface of the liquid in the tank 100, although this is not required in all embodiments. Regardless, as the one or more semiconductor wafers pass through the liquid to IPA vapor interface, the one or more semiconductor wafers are quickly dried due at least in part to the creation of a surface tension gradient between the isopropyl alcohol and the liquid in the tank 100 at the surface.

Referring to FIGS. 1-3 and 7B, the tank 100 comprises an interior cavity 101 that is configured to hold the liquid such as deionized water. In the exemplified embodiment, the tank 100 comprises a main body portion 110 that defines a first portion 111 of the interior cavity 101 and a lid portion 120 that defines a second portion 121 of the interior cavity 101. However, the structural details of the tank 100 are not to be limiting of the present invention in all embodiments and variations are certainly possible and may fall within the scope of the invention claimed herein. In particular, in some embodiments the tank 100 may not include a lid portion 120, or the lid portion 120 may be included but be a flat plate such that it does not define any part of the interior cavity 101 of the tank 100. The lid portion 120 may be movable between an open position whereby the top end of the tank 100 is open and a closed position whereby the lid portion 120 closes the open top end of the tank 100. The lid portion 120 may be moved to the open position during insertion and removal of the semiconductor wafers from the interior cavity 101 of the tank 100, which may be accomplished manually by a user or automatically by a robot.

The tank 100 may also comprise a drain so that any liquid introduced into the tank 100 may be drained as desired or needed. The tank 100 may comprise the interior cavity 101 and an overflow cavity (not shown) in some embodiments so that liquid which overflows the interior cavity 101 may flow into the overflow cavity during a drying operation.

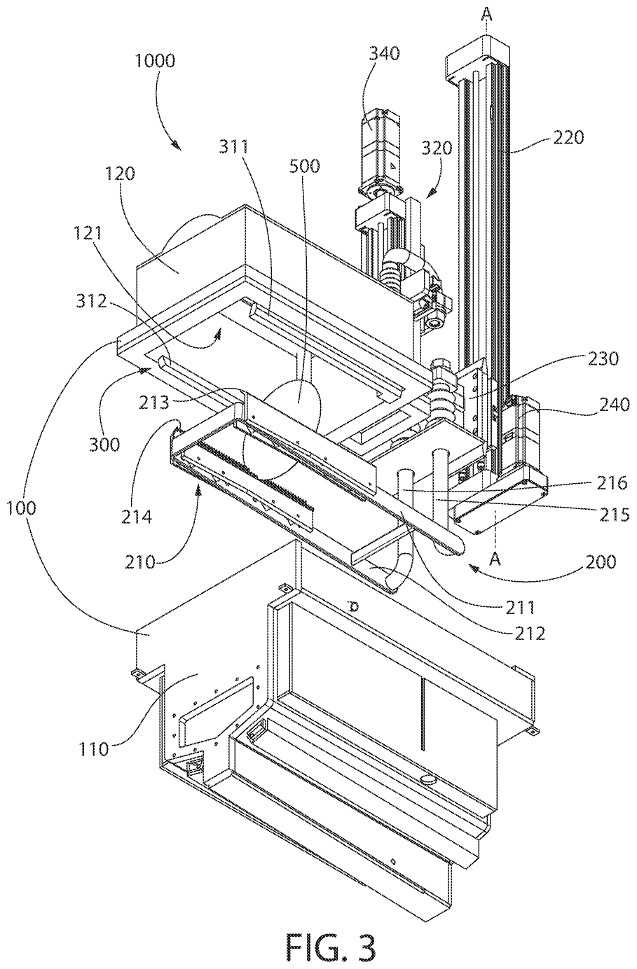

The first lifting assembly 200 comprises a first wafer carrier 210 that is configured to hold the one or more semiconductor wafers (a single semiconductor wafer 500 is illustrated being held by the first wafer carrier 210 in FIG. 3, although it should be appreciated that the first wafer carrier 210 is configured to hold a plurality of semiconductor wafers in a vertical orientation). In the exemplified embodiment, the first wafer carrier 210 comprises a first carrier arm 211 and a second carrier arm 212 that are positioned parallel to one another in a spaced apart manner. The first carrier arm 211 comprises a first set of combs 213 and the second carrier arm 212 comprises a second set of combs 214. The first and second sets of combs 213, 214 are essentially recesses or slots within which portions of an outer peripheral region of the one or more semiconductors may nest when supported by the first wafer carrier 210.

The first wafer carrier 210 is configured to support one or more wafers such that each wafer is positioned between two adjacent ones of the first set of combs 213 and two adjacent ones of the second set of combs 214 that are in alignment with the two adjacent ones of the first set of combs 213. Of course, other structures for holding the one or more semiconductor wafers may be used in other embodiments. For example, the first wafer carrier 210 may comprise a cassette in some embodiments that is configured to hold the one or more wafers. Thus, the exact structural details of the first and second carrier arms 211, 212 of the first wafer carrier 210 are not limiting of the present invention in all embodiments and variations are possible within the scope of the invention claimed herein. Moreover, in some embodiments the first wafer carrier 210 may be a continuous structure with a floor such that it does not have carrier arms, but instead has lateral surfaces at the location of the carrier arms.

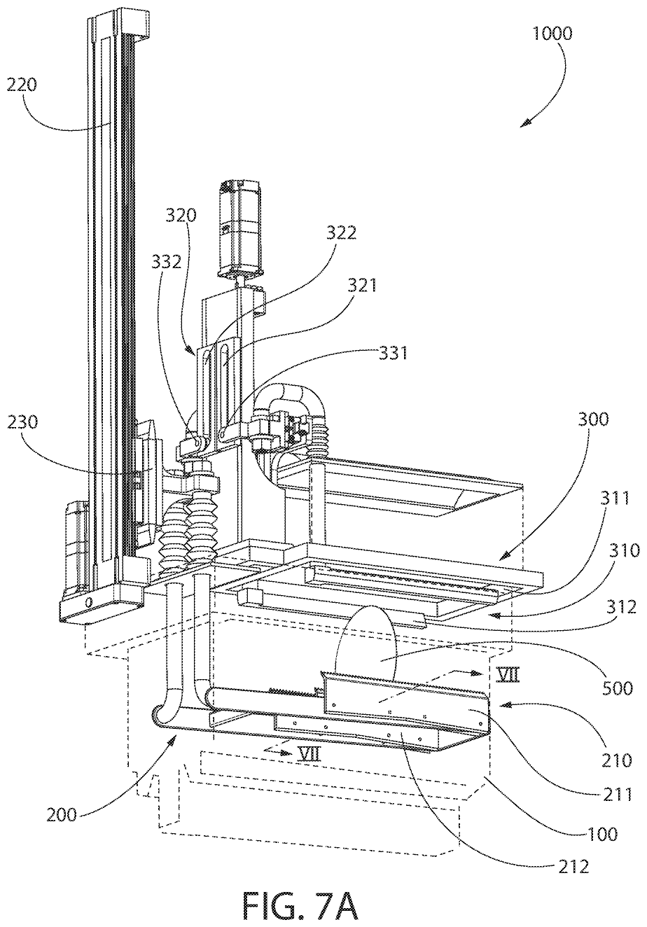

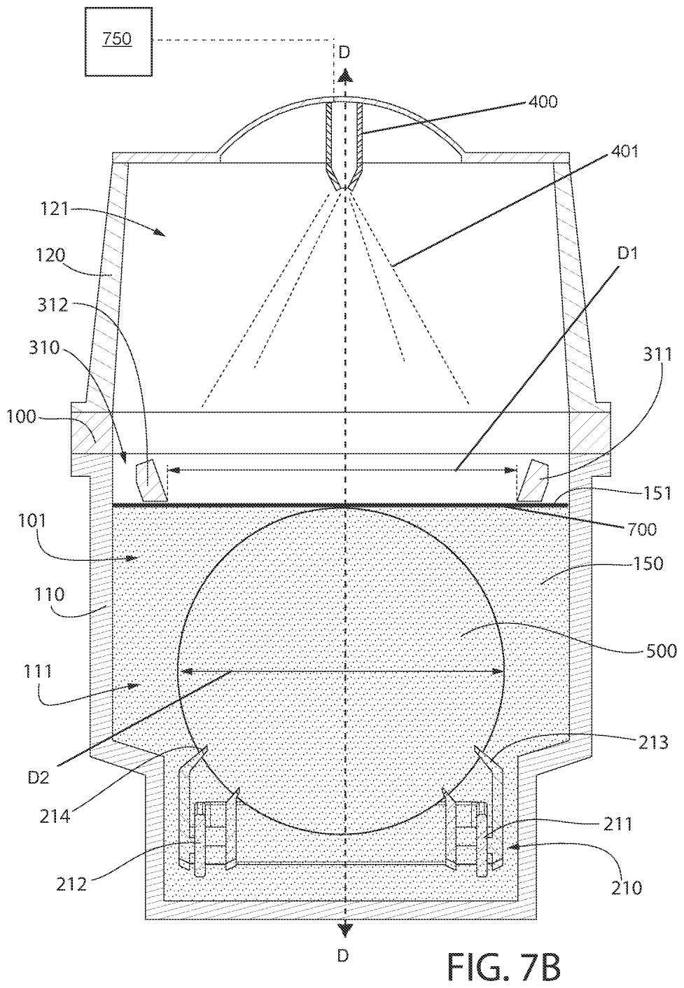

As seen in FIG. 7B, the first and second carrier arms 211, 212 both comprise two rows of the combs. This structure may be used to ensure that the first and second carrier arms 211, 212 are configured to support the one or more semiconductor wafers 500 in an upright/vertical orientation. That is, the one or more semiconductor wafers 500 should be maintained in the upright/vertical orientation so that the front and rear surfaces of the semiconductor wafer 500 are both oriented along a vertical plane or axis. This is the best way to achieve effective drying of the one or more semiconductor wafers 500 as the one or more semiconductor wafers 500 are raised out of the liquid 150 in the tank 100.

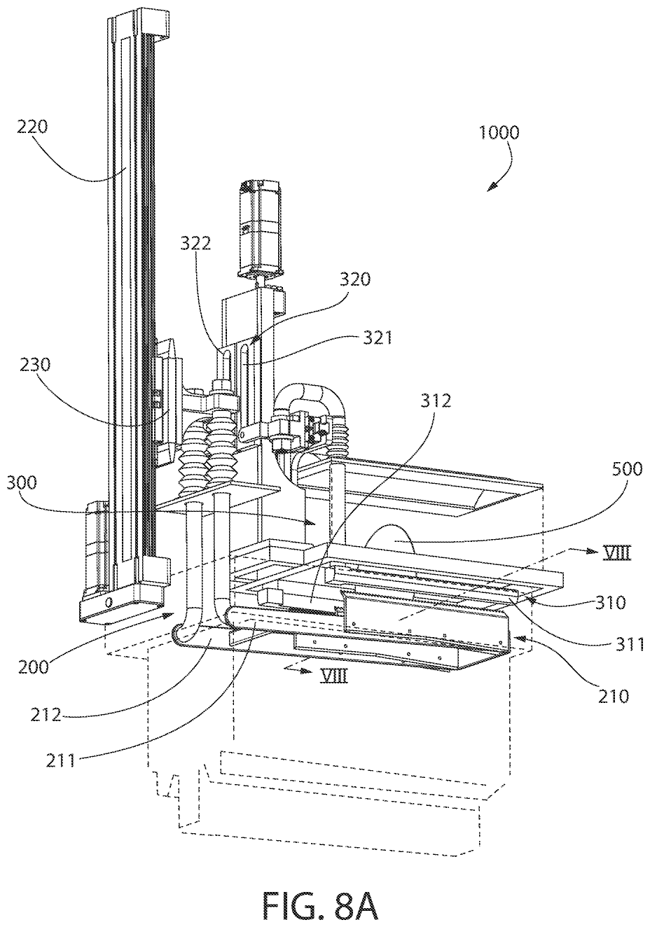

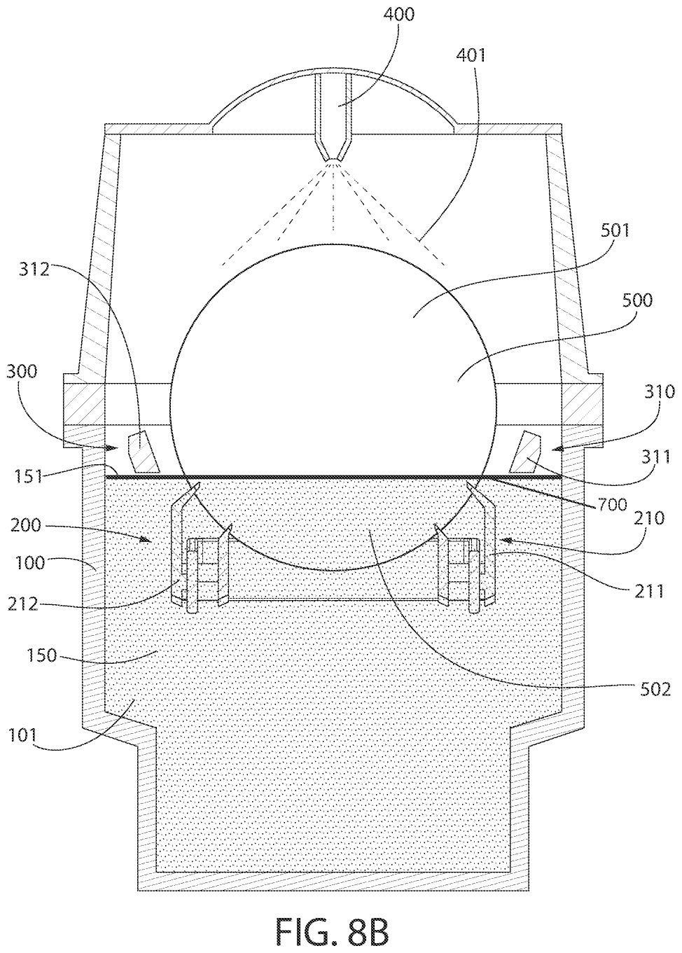

The first lifting assembly 200 comprises a vertical first track structure 220, a clamp member 230 that is coupled to the vertical first track structure 220, and a first motor 240 that controls movement of the clamp member 230 along the vertical first track structure 220. The first and second carrier arms 211, 212 of the first wafer carrier 210 are coupled to the clamp member 230 by a vertical carrier arm 215, 216. The clamp member 230 is coupled to and rides along the vertical first track structure 220 along a vertical axis A-A. That is, the clamp member 230 operates as a follower member and comprises a structure that engages and rides along the vertical first track structure 220 when the motor 240 is activated. The clamp member 230 and the vertical first track structure 220 may have mating structures that maintain the coupling between the clamp member 230 and the vertical first track structure 220 while permitting the clamp member 230 to move along the first track structure 220 during operation of the apparatus 1000. When the first motor 240 is activated, the clamp structure 230 rides either upwardly or downwardly along the vertical first track structure 220 (depending on the rotational direction of the motor 240), which causes the first wafer carrier 210 and the first and second carrier arms 211, 212 that are coupled to the clamp structure 230 to move vertically upwardly and downwardly in the direction of the vertical axis A-A. When the first wafer carrier 210 is carrying one or more semiconductor wafers 500, the semiconductor wafers 500 similarly move upwardly and downwardly in the vertical direction of the vertical axis A-A along with the clamp member 230. FIGS. 1-3 illustrate the first lifting assembly 200 in its lowermost position. FIG. 8A illustrates the first lifting assembly 200 in its raised position, whereby the clamp structure 230 has moved vertically upward along the vertical first track structure A-A.

The first lifting assembly 200 is configured to carry the semiconductor wafers 500 positioned thereon for a distance out of the liquid bath, but not the entire way out of the liquid bath. The reason for this is that there is a desire to eliminate contact points between the lifting assemblies and the semiconductor wafers 500 as the semiconductor wafers emerge from the liquid. Specifically if a portion of the semiconductor wafer 500 emerges from the liquid while being contacted by the first lifting assembly 200, the portion of the semiconductor wafer 500 that is being contacted will be prevented from adequately drying. In particular, the effects of the IPA vapor and the tension gradient will not be imparted to those portions of the semiconductor wafer 500 that are contacted by the first lifting assembly 200 as the semiconductor wafer 500 passes through the surface of the liquid in the tank. Thus, by neglecting to raise the first lifting assembly 200, or at least portions thereof that are in contact with the semiconductor wafer 500, out of the liquid in the tank 100, this prevents water spots and helps to ensure a more thorough drying of the semiconductor wafers 500. After the semiconductor wafers 500 are partially lifted out of the liquid by the first lifting assembly 200, the semiconductor wafers 500 are transferred to the second lifting assembly 300, which then lifts the semiconductor wafers 500 the rest of the way out of the liquid. Importantly, the second lifting assembly 300 only makes contact with portions of the semiconductor wafers 500 which have already been lifted out of the liquid and dried. Portions of the second lifting assembly 300 that are intended to contact the semiconductor wafer 500 are never submerged in or otherwise put in contact with the liquid in the tank 100.

The second lifting assembly 300 comprises a second wafer carrier 310 that is configured to carry and lift the semiconductor wafers 500 out of the liquid in the tank 100 after being transferred from the first wafer carrier 210 of the first lifting assembly 300 as described herein. The second wafer carrier 310 may comprise a first carrier arm 311 and a second carrier arm 312. The first and second carrier arms 311, 312 may be oriented parallel to one another in a spaced apart manner. Moreover, the first and second carrier arms 311, 312 may be oriented parallel to the first and second carrier arms 211, 212 of the first wafer carrier 210 described above in some embodiments. As best shown in FIG. 7B, the tank 100 has a longitudinal axis D-D that extends from a floor of the tank to an open top end of the tank. The first and second carrier arms 311, 312 may be located on opposite sides of the longitudinal axis D-D of the tank 100.

Although not shown in the exemplified embodiment, the first and second carrier arms 311, 312 of the second wafer carrier 310 may comprise combs much like the combs 213, 214 of the first and second carrier arms 211, 212 of the first wafer carrier 210 to enable the first and second carrier arms 311, 312 to support the one or more semiconductor wafers 500 and maintain them in their upright orientation as shown. That is, there may be slots or grooves formed into the outer surface of the first and second carrier arms 311, 312 within which edge portions of the semiconductor wafers 500 may nest to facilitate the engagement between the first and second carrier arms 311, 312 and the semiconductor wafers 500. The first and second carrier arms 211, 212 may include other structures to achieve this instead of the combs, and in still other embodiments there may be no added features to that which is depicted in the drawings, so long as the first and second carrier arms 311, 312 are capable of holding, supporting, and carrying support the semiconductor wafers 500 in the upright orientation. The first and second carrier arms 311, 312 may have outer surfaces which face one another and which are angled so as to diverge from one another with increasing distance from the first wafer carrier 210 (i.e., moving in a direction from a floor of the tank 100 to a roof of the tank 100).

Moreover, while the first and second carrier arms 311, 312 are depicted as elongated bar-like rods, the invention is not to be so limited in all embodiments. In other embodiments, the first and second carrier arms 311, 312 may be arcuate plates having a concave inner surface that faces the semiconductor wafers 500. This may facilitate a better engagement between the first and second carrier arms 311, 312 and the semiconductor wafers 500 to ensure that the first and second carrier arms 311, 312 hold the semiconductor wafers 500 in the upright orientation during use.

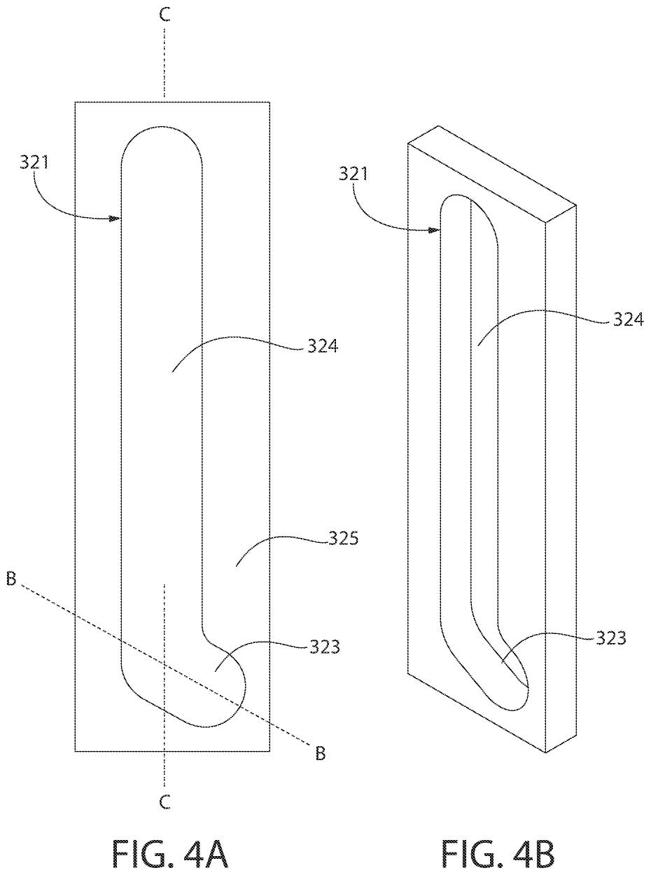

The second lifting assembly 300 may comprise a second track structure 320. The second track structure 320 may comprise a first track 321 and a second track 322. In the exemplified embodiment, each of the first and second tracks 321, 322 is a slot forming a pathway within which follower members of the second lifting assembly 300 move. The details of the shape and orientation of the first and second tracks 321, 322 will be provided below with reference to FIGS. 4A and 4B.

The second lifting assembly 300 comprises a first follower member 331 that nests within and/or otherwise and rides along the first track 321 and a second follower member 332 that nests within and/or and rides along the second track 322. The first follower member 331 is coupled to the first carrier arm 311 and the second follower member 332 is coupled to the second carrier arm 312. Thus, the movement of the first follower member 331 along the first track 321 dictates the path of movement of the first carrier arm 312 whereas the movement of the second follower member 332 along the second track 322 dictates the path of movement of the second carrier arm 312. In the exemplified embodiment, each of the first and second follower members 331, 332 comprises a protuberance that nests within the slots of the first and second tracks 321, 322, respectively. Of course, in other embodiments the follower members 331, 332 could be slots and the tracks 321, 322 could be protuberances, or some other arrangement of parts may be possible while still enabling the movement of the second lifting assembly 300 as described further herein below. In the exemplified embodiment, there is a second motor 340 distinct from the first motor 240 that controls movement of the second lifting assembly 300. However, in other embodiments the same motor may be configured to control the movement of both of the first and second lifting assemblies 200, 300.

Referring to FIGS. 4A and 4B, the first track 321 of the second track structure 320 will be described. It should be appreciated that the second track 322 is a mirror image of the first track 321, so the description of the first track 321 is applicable to the second track 322. As noted above, the first track 321 comprises or is a slot, channel, or the like formed into or through a plate 325 and within which the first follower member 331 can nest and move/slide during movement of the second lifting assembly 300. The first track 321 comprises a bottom portion 323 that extends along a first axis B-B and a top portion 324 that extends along a second axis C-C. The second axis C-C is oriented vertically (i.e., perpendicular to the horizon), and the first axis B-B is oriented at an angle relative to the second axis C-C. In the exemplified embodiment, the first axis B-B is oblique to the second axis C-C. The first axis B-B may intersect the second axis C-C at an angle of between 15° and 75°, more specifically between 30° and 60°, and still more specifically between 40° and 50°. However, the first axis B-B may be perpendicular to the second axis C-C in some alternative embodiments. Thus, the first track 321 is a slot or aperture having a generally “L” shape, with the bottom leg of the “L being angled downwardly and away from the vertical leg of the “L.”

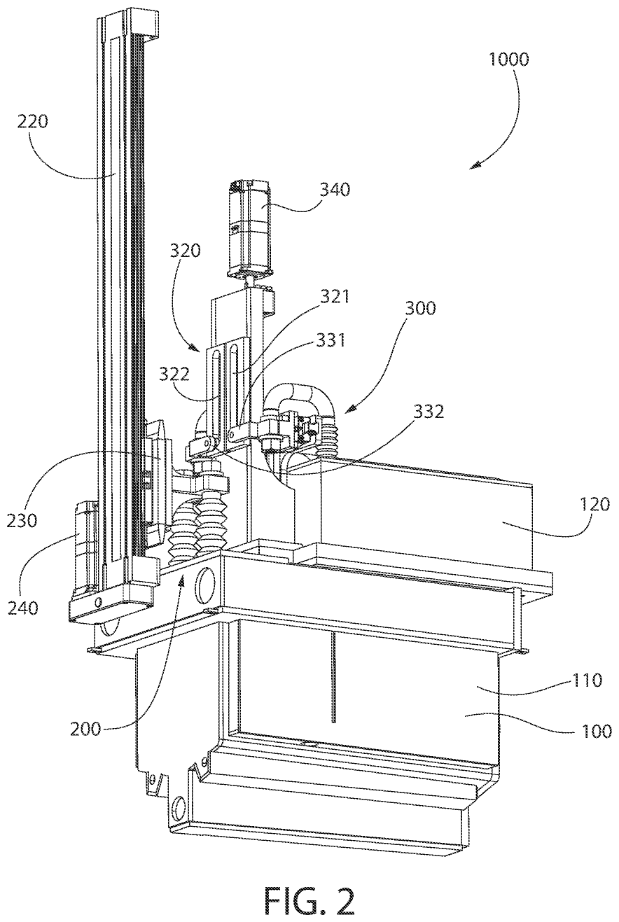

Referring to FIGS. 2, 4A, and 4B, the first and second tracks 321, 322 are positioned and oriented so that the bottom portions 323 thereof are angled towards one another as they extend in the direction towards the top portions 324 thereof. Stated another way, as the first and second follower members 331, 332 ride along the bottom portions 323 of the first and second tracks 321, 322, the first and second follower members 331, 332 move inwardly towards one another. At the same time, because the first and second follower members 331, 332 are coupled to the first and second carrier arms 311, 312, the first and second carrier arms 311, 312 also move in an inward direction towards one another as the first and second follower members 331, 332 move upwardly along the bottom portions 323 of the first and second tracks 321, 322 towards the top portions 324 of the first and second tracks 321, 322. The top portions 324 of the first and second tracks 321, 322 are oriented in a vertical direction, such that when the first and second follower members 331, 332 move upwardly along the top portions 324 of the first and second tracks 321, 322, the first and second carrier arms 311, 312 move in a vertical upward direction to lift the semiconductor wafers 500 out of the liquid in the tank 100, as described herein below.

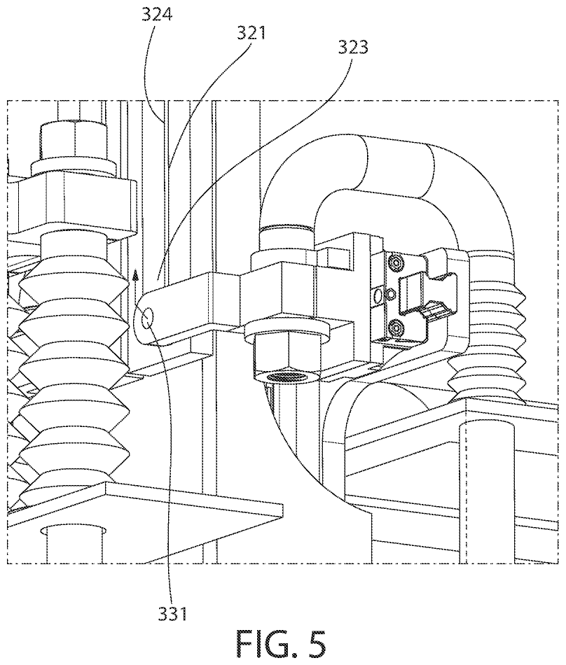

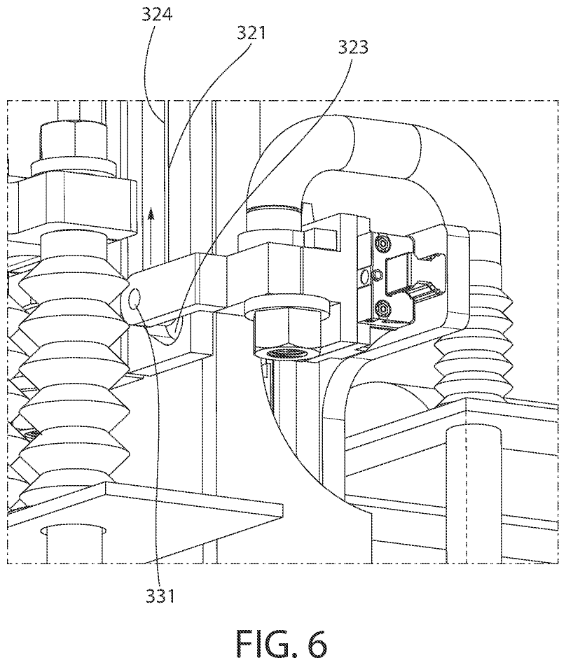

Referring briefly to FIGS. 5 and 6, a close-up illustration is provided showing the movement of the first follower member 331 within the first track 321 of the second track structure 320. Specifically, FIGS. 5 and 6 illustrate how the first follower member 331 moves inwardly and upwardly along the bottom portion 323 of the first track 321 and then vertically upwardly within the top portion 324 of the first track 321.

As will be discussed in greater detail below, when the first and second follower members 331, 332 are in their lowermost position along the bottom end of the bottom portions 323 of the first and second tracks 321, 322, the first and second carrier arms 311, 312 are spaced apart from one another a distance D1 (specifically, a minimum distance) that is greater than a diameter D2 of the semiconductor wafers 500 (see FIG. 7B). Thus, in this lowermost position, the first and second carrier arms 311, 312 are unable to engage the semiconductor wafers 500 for purposes of carrying them upward and out of the liquid in the tank 500. This is necessary so that the first lifting assembly 200 can lift the semiconductor wafers 500 at least partially out of the liquid in the tank 100 without interference by the second lifting assembly 300. The semiconductor wafers 500 pass through the space between the first and second carrier arms 311, 312 while the semiconductor wafers 500 are lifted/raised by the first wafer carrier 210. Once the semiconductor wafers 500 are out of the liquid in the tank 100 by a sufficient amount, the second lifting assembly 300 is activated which causes the first and second carrier arms 311, 312 to move inwardly towards one another and towards the semiconductor wafers 500 to engage (i.e., initiate contact with) the semiconductor wafers 500 for purposes of carrying them further out of the liquid in the tank 100.

It should be appreciated that the apparatus 1000 may comprise a processor or controller or control unit that automatically activates the movement of the first and second lifting assemblies 200, 300 in a proper timing sequence to properly remove the semiconductor wafers 500 from the liquid in the tank 100 at a sufficiently slow rate for the Marangoni process to adequately dry the semiconductor wafers 500. In particular, the apparatus 1000 may in some embodiments comprise a processor and a memory device. The processor and memory device may be separate components, or the memory device may be integrated with the processor within the control unit. Furthermore, the control unit may include only one processor and one memory device, or it may include multiple processors and multiple memory devices. The processor of the control unit may be any computer or central processing unit (CPU), microprocessor, micro-controller, computational device, or circuit configured for executing some or all of the processes described herein, including without limitation: activation and deactivation of the first and second motors 240, 340; activation and deactivation of isopropyl alcohol injection; filling of the tank 100 with the liquid, recirculating the liquid within the tank 100, and other process steps which may be automated by such a processor.

The memory device of the control unit may include, without limitation, any suitable volatile or non-volatile memory including random access memory (RAM) and various types thereof, read-only memory (ROM) and various types thereof, USB flash memory, and magnetic or optical data storage devices (e.g. internal/external hard disks, floppy discs, magnetic tape CD-ROM, DVD-ROM, optical disk, ZIP™ drive, Blu-ray disk, and others), which may be written to and/or read by the processor which is operably connected thereto. The memory device may store algorithms and/or calculations that can be used by the processor to determine when to activate/deactivate the various motors, valves, heat sources, injectors, and the like which are described herein.

FIG. 1 illustrates a processor 600 schematically. The processor 600 is operably coupled to each of the first and second motors 240, 340. Thus, the processor 600 may store instructions which guide the activation of the first and second motors 240, 340 in a sequential manner to achieve the operation of the apparatus 1000 as described herein. That is, the processor 600 is configured to activate the motor 240 to cause the first lifting assembly 200 to move from the first lowered position to the first raised position and then the processor 600 is configured to activate the second motor 340 to cause the second lifting assembly 300 to move from the second lowered position to the second raised position. The processor 600 may activate the second motor 340 just prior to the first lifting assembly 200 reaching the first raised position to allow for a continuous raising/lifting of the semiconductor wafers out of the liquid in the tank 100. Alternatively, the processor 600 may wait until the first lifting assembly 200 reaches the first raised position before activating the motor 340.

Referring to FIGS. 7A-10B, the method of drying one or more semiconductor wafers using the apparatus 1000 will be described.

Referring first to FIGS. 7A and 7B, the first and second lifting assemblies 200, 300 are in their lowered or lowermost positions, which is their position at the start of the Marangoni drying process. At this point in the process, the tank 100 is filled with a liquid 150 (i.e., deionized water). The first wafer carrier 210 of the first lifting assembly 200 is located within the interior cavity 101 of the tank 100 and is completely submerged in the liquid 150. The first wafer carrier 210 is holding or supporting one or more semiconductor wafers 500, and the semiconductor wafers 500 are also completely submerged in the liquid 150 in the tank 100. As noted above, the liquid 150 may be a deionized water. The liquid 150 may continue to drain and replenish during the process rather than remaining stagnant, and in such embodiments the apparatus 1000 may include a drain for draining the liquid 150 from the interior cavity 101 of the tank 100 and a nozzle for introducing more of the liquid 150 into the interior cavity 101 of the tank 100.

Furthermore, at this point in the process the second wafer carrier 310 of the second lifting assembly 300 is located outside of the liquid 150. That is, the liquid 150 has a surface level 151, and the second wafer carrier 310 is located within the internal cavity 101 of the tank 110, but no part thereof is submerged in the liquid 150 because it is located between the surface level 151 of the liquid 150 and the roof of the tank 100. As a result, the second wafer carrier 310 is completely dry. In some embodiments, the second wafer carrier 310 may never contact the liquid 150 in the tank 100 so that the second wafer carrier 310 stays completely dry. As noted above, the diameter D2 of the semiconductor wafer 500 is less than the distance D1 between the first and second carrier arms 311, 312 of the second wafer carrier 310. This is important because it ensures that there is sufficient space for the semiconductor wafer 500 to fit between the first and second carrier arms 311, 312 of the second wafer carrier 310 as the first lifting assembly 200 lifts the semiconductor wafer 500 out of the liquid 150.

As best seen in FIG. 7A, when the first lifting assembly 200 is in its lowered position, the clamp member 230 is positioned at the bottom of the vertical first track structure 220. The clamp member 230 is unable to move downwardly, and can only move upwardly along the first track structure 220 (hence stating that the first lifting assembly 200 is in the lowered or lowermost position). Similarly, when the second lifting assembly 300 is in its lowered position, the follower members 331, 332 are located along the bottommost part of the bottom portion 323 of the first and second tracks 321, 322.

Referring to FIGS. 8A and 8B, the apparatus 1000 is illustrated with the first lifting assembly 200 having been moved from the lowered or lowermost position to its raised position. To so move the first lifting assembly 200, the processor 600 activates the first motor 240, which causes the clamp member 230 of the first lifting assembly 200 to move vertically upwardly along the vertical first track structure 220 (compare the position of the clamp member 230 in FIG. 7A with the position of the clamp member 230 in FIG. 8A). In the provided figures, the first vertical track structure 220 is quite long, and it appears that the clamp member 230 could move further along the first vertical track structure 220 than the position shown in FIG. 8A. However, there may be a stopper feature which prevents the clamp member 230 from moving beyond the position shown in FIG. 8A. Alternatively, in other embodiments the vertical first track structure 220 may be shorter than depicted so that the position of the clamp member 230 in FIG. 8A is the uppermost position of the first lifting assembly 200.

In some embodiments, as the first lifting assembly 200 moves from the lowered position (FIGS. 7A and 7B) to the raised position (FIGS. 8A and 8B), isopropyl alcohol vapor may be sprayed onto the semiconductor wafers 500 or otherwise introduced into the interior cavity 101 of the tank 100 as the semiconductor wafers 500 emerge through the surface level 151 of the liquid 150. This is shown generically in FIG. 7B whereby a nozzle 400 is illustrated spraying the IPA vapor 401 into the internal cavity 101 of the tank 100. The invention is not limited to spraying IPA vapor, and any volatile organic compound (VOC) may be used in other embodiments. The nozzle 400 may be operably coupled to a source of IPA 750 or IPA/N₂, or any other VOC as may be used. Furthermore, in some embodiments an IPA/N₂ vapor may be sprayed. The IPA vapor may form a layer of the IPA vapor 700 atop of the surface level 151 of the liquid 150. Thus, when the semiconductor wafers 500 are lifted through the surface level 151 of the liquid 150, they will pass through the layer of the IPA vapor 700 (or other VOC). As this occurs, the IPA or VOC dissolves into the water at the surface/meniscus, creating a surface tension gradient which causes the meniscus to partially contract. This results in the thin water film flowing off the substrate/semiconductor wafer 500, leaving it dry and removing contaminants and particles.

While only a single nozzle 400 is shown, there may be multiple nozzles 400 spraying the IPA (or other VOC) vapor 401 into the internal cavity 101 of the tank 100 in other embodiments or other components that achieve the introduction of the IPA vapor 401 into the tank 100. The nozzles 400 may be located along the sidewalls of the lid rather than along the roof thereof. Moreover, other methods of introducing the IPA vapor 401 into the internal cavity 101 of the tank 100 may be employed as long as the IPA vapor 401 introduces a surface tension gradient where it interfaces with the liquid 150 on the liquid surface 151 to facilitate a quick drying of the semiconductor wafer 500. Thus, as the semiconductor wafer 500 emerges through the surface level 151 of the liquid 150, the semiconductor wafer 500 becomes dry.

The IPA vapor may continue to be introduced into the tank 100 while the semiconductor wafers 500 are raised/lifted out of the liquid (see FIG. 8B). However, this is not required in all embodiments and in some embodiments the IPA vapor may be introduced prior to raising the semiconductor wafers 500 out of the liquid 150, but not during the raising of the semiconductor wafers 500 out of the liquid.

In some embodiments, the injection of the IPA into the tank 100 may stop before the first lifting assembly 200 is activated. In other embodiments, the IPA may continue to be injected into the tank 100 even during the raising of the semiconductor wafers 500 out of the liquid 150. However, generally it is preferable to start the IPA vapor introduction prior to raising/lifting the semiconductor wafers 500 out of the liquid 150 so that the layer of the IPA vapor 700 exists on top of the surface level 151 of the liquid 150 as the semiconductor wafers 500 emerge through the surface level 151 of the liquid 150. As such, once the semiconductor wafers 500 break through the surface level 151 of the liquid 150, the semiconductor wafers 500 will quickly dry by the Marangoni effect.

When the first lifting assembly 200 reaches the raised position as shown in FIGS. 8A and 8B, the first wafer carrier 210 including both of the first and second carrier arms 211, 212 remain completely submerged in the liquid 150. This ensures that the semiconductor wafers 500 do not penetrate through the surface level 151 of the liquid 150 while being contacted by the first lifting assembly 200, as this could result in inadequate drying and spots. When the first lifting assembly 200 is in the raised position, an upper portion 501 of the one or more semiconductor wafers 500 is positioned outside of the liquid 150 (i.e., above the surface level 151 of the liquid 150) and a bottom portion 502 of the one or more semiconductor wafers 500 remain submerged in the liquid 500. In the exemplified embodiment, more than half of the semiconductor wafer 500 is located outside of the liquid 150 when the first lifting assembly 200 is in the raised position. Thus, the upper portion 501 of the one or more semiconductor wafers 500 which are not positioned in the liquid 150 are dry due to the Marangoni effect as described herein and known by persons skilled in the art. This allows the second wafer carrier 310 of the second lifting assembly 300 to engage portions of the semiconductor wafer 500 which are already dry, and to then lift the remainder of the semiconductor wafers 500 out of the liquid 150. As such, the first and second lifting assemblies 200, 300 are never in contact with a portion of the semiconductor wafer 500 as it is passing through the surface level 151 of the liquid 150.

Also as seen in FIG. 8B, and as mentioned above, because the minimum distance D1 between the first and second carrier arms 311, 312 of the second lifting assembly 310 is greater than the diameter D2 of the semiconductor wafer(s) 500, the semiconductor wafer(s) 500 pass through the space between the first and second carrier arms 311, 312 as they are raised/lifted out of the liquid 150 by the first lifting assembly 200.

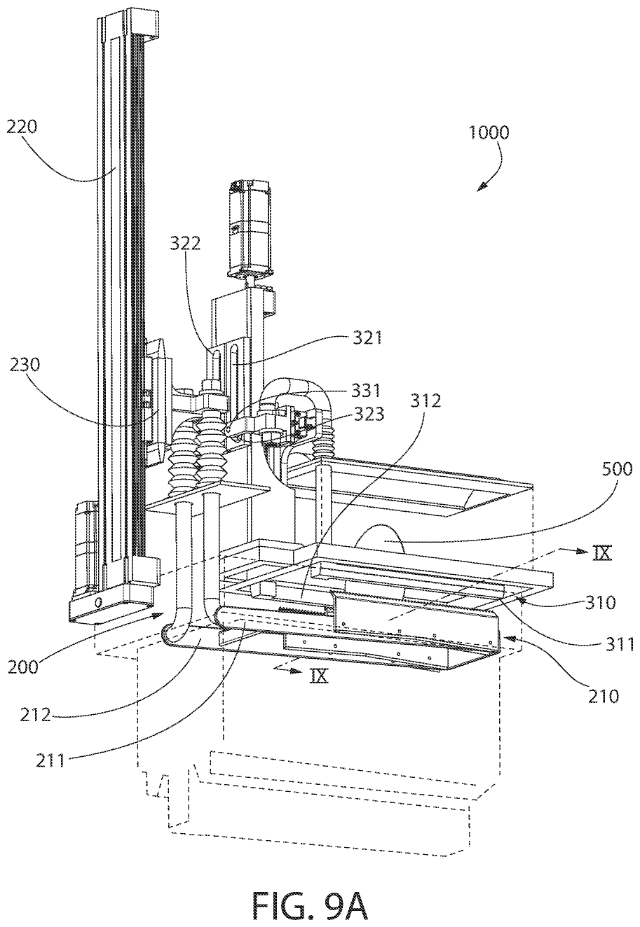

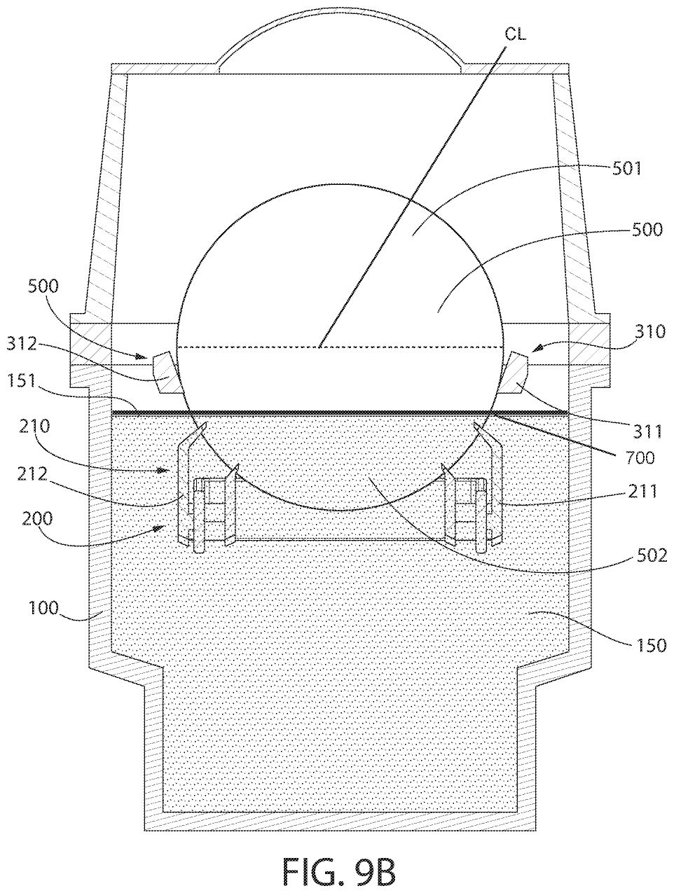

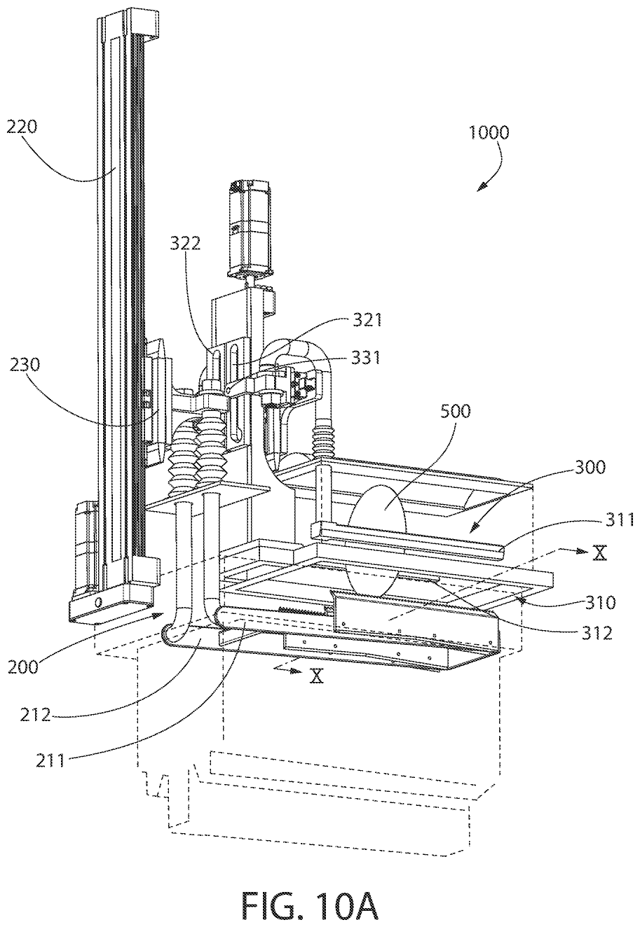

Referring to FIGS. 9A and 9B, the next step in the process is to begin moving the second lifting assembly 300 so that the first and second carrier arms 311, 312 engage the semiconductor wafers 500 for purposes of lifting the semiconductor wafers 500 the remaining distance out of the liquid 150 in the tank 100. This may be achieved by the processor 600 actuating the motor 340. In some embodiments, the second lifting assembly 300 may be activated to start moving the follower members 331, 332 along the first and second tracks 321, 322 prior to the first lifting assembly 200 reaching its final raised position. That is, just before the first lifting assembly 200 reaches its final raised position, the second lifting assembly 300 may be activated so that the first and second carrier arms 311, 312 engage the semiconductor wafers 500 just as the first lifting assembly 200 reaches its final raised position and stops moving. This may ensure that the semiconductor wafers 500 move continuously without any stoppage until they are fully removed from the liquid 150 in the tank 100. However, in other embodiments the second lifting assembly 300 may not be activated until the first lifting assembly 200 reaches its final raised position. In such an embodiment, the semiconductor wafers 500 may be temporarily stationary as the first and second carrier arms 311, 312 move from the position shown in FIG. 8B to the position shown in FIG. 9B. It may be preferable to activate the second lifting assembly 300 to start moving before the first lifting assembly 200 stops moving in order to maintain the continuous movement of the semiconductor wafers 500, but this is not required in all embodiments.

The first and second carrier arms 311, 312 of the second wafer carrier 310 engage the semiconductor wafer 500 along an edge thereof. That is, the semiconductor wafers 500 have a front surface, a rear surface, and an edge extending between the front and rear surfaces. It is generally preferable to avoid contact with the front and rear surfaces of the semiconductor wafers 500 to the extent possible. Thus, the first and second carrier arms 311, 312 may engage/contact with semiconductor wafers 500 along their edges rather than along their front and/or rear surfaces.

As shown in FIGS. 9A and 9B, the first and second follower members 331, 332 have moved from the bottommost part of the bottom portion 323 of the tracks 321, 322 to an uppermost part of the bottom portion 323 of the tracks 321, 322. This movement of the first and second follower members 331, 332 along the first and second tracks 321, 322 causes the first and second carrier arms 311, 312 to move slightly upwardly and also inwardly towards one another (compare the position of the first and second carrier arms 311, 312 in FIG. 8B to the position of the first and second carrier arms 311, 312 in FIG. 9B). This is due to the orientation of the bottom portion 323 of the tracks 321, 322, which are angled inwardly towards one another in order to move the first and second carrier arms 311, 312 inwardly towards one another and towards the semiconductor wafers 500. Thus, the movement of the second wafer carrier 210 from the second lowered position (the positions shown in FIG. 8B) to a transfer position (the position shown in FIG. 9B) moves the first and second carrier arms 210 into engagement/contact with the semiconductor wafers 500. When in the transfer position, the first and second carrier arms 311, 312 contact the semiconductor wafers 500 at a position below a horizontal centerline CL of the semiconductor wafers 500.

As shown in FIG. 9B, the first and second carrier arms 311, 312 of the second lifting assembly 300 are in engagement with the semiconductor wafers 500 such that upward movement of the first and second carrier arms 311, 312 will lift the lower portions 502 of the semiconductor wafers 500 which remain in the liquid 150 upward and out of the liquid 150 in the tank 100. More specifically, as the second wafer carrier 310 moves upwardly from the position shown in FIG. 9B, the second wafer carrier 310 takes over the job of supporting the one or more semiconductor wafers 500 from the first wafer carrier 210. That is, once the second wafer carrier 310 begins to raise or lift, the one or more semiconductor wafers 500 become fully supported by the second wafer carrier 310 and are no longer supported by the first wafer carrier 210. As the second wafer carrier 310 is raised, the one or more semiconductor wafers 500 are lifted off of and move away from the first wafer carrier 210 as they continue to be lifted out of the liquid 150 in the tank 100.

As noted above, the first and second carrier arms 311, 312 are illustrated simplistically, but may have grooves, cassettes, slots, teeth, combs, or other structure for holding the semiconductor wafers 500 upright as shown in other embodiments. The first and second carrier arms 311, 312 are never submerged or otherwise put into contact with the liquid 150, and thus the first and second carrier arms 311, 312 remain completely dry and contact between the first and second carrier arms 311, 312 and the semiconductor wafer 500 will not create any wet spots on the semiconductor wafer 500.

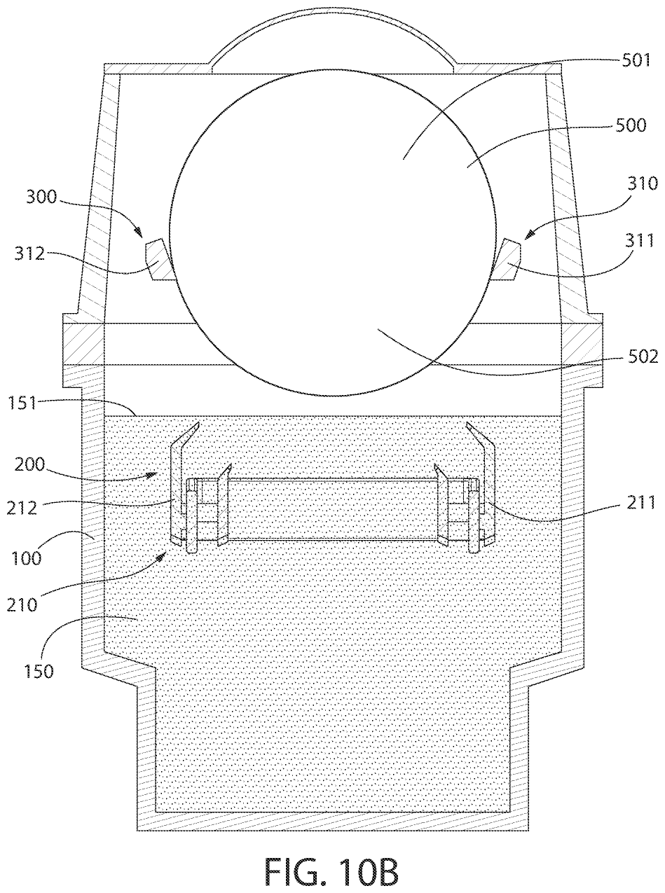

Referring to FIGS. 10A and 10B, continued movement of the first and second follower members 331, 332 along the first and second tracks 321, 322 causes the first and second carrier arms 311, 312 to move vertically upward. As the first and second carrier arms 311, 312 move upwardly away from the transfer position (FIG. 9B) and towards the second raised position (FIG. 10B), the first and second carrier arms 311, 312 take over supporting the semiconductor wafers 300 from the first wafer carrier 210. That is, as the second wafer carrier 310 begins to move upwardly from the transfer position, the second wafer carrier 310 fully supports the semiconductor wafers 500 which are no longer in contact with the now stationary first wafer carrier 210. The second lifting assembly 200 and the second wafer carrier 210 thereof continue to move vertically from the transfer position (FIG. 9B) to the second raised position (FIG. 10B). Because the first and second carrier arms 311, 312 are now carrying/supporting the semiconductor wafers 500, the semiconductor wafers 500 are pulled upwardly out of the liquid 150 in the tank 100. The first and second follower members 331, 332 move along the first and second tracks 321, 322 until the entirety of the semiconductor wafers 500 are removed from the liquid 150 in the tank 100.

As shown in FIG. 9B, the first and second carrier arms 311, 312 of the second lifting assembly 300 engage a part of the upper portions 501 of the semiconductor wafers 500, which have already been dried by Marangoni effect prior to the engagement with the first and second carrier arms 311, 312 of the second wafer carrier 310. Thus, there is no structure touching the semiconductor wafers 500 as they are initially moved through the liquid level 151 of the liquid 150 in the tank 100. This results in a more effective drying without any water marks or spots that would result if there were contact between the carrier arms 311, 312 and the semiconductor wafers 500 as the semiconductor wafers 500 are pulled out of the liquid 150 in the tank 100.

Although not shown, the next step in the process is to slowly drain the liquid 150 from the tank 100 to dry the first wafer carrier 210 via the Marangoni effect and to lower the first wafer carrier 210 from the first raised position back to the first lowered position. Once the first wafer carrier 210 is dried, the second lifting assembly 300 may be lowered to place the semiconductor wafers 500 back onto the first wafer carrier 210 of the first lifting assembly 200. Alternatively, a robot or other handling device may remove the semiconductor wafers 500 from the second lifting assembly 300 for further processing.

While the invention has been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present invention. Thus, the spirit and scope of the invention should be construed broadly as set forth in the appended claims.

What is claimed is:

1. An apparatus for drying semiconductor wafers, the apparatus comprising:
a tank containing a liquid;
a first lifting assembly comprising a first wafer carrier configured to hold one or more semiconductor wafers, the first lifting assembly being operable to move the first wafer carrier between a first lowered position wherein the one or more semiconductor wafers are completely submerged in the liquid in the tank and a first raised position wherein a lower portion of the one or more semiconductor wafers remain submerged in the liquid in the tank and an upper portion of the one or more semiconductor wafers is no longer submerged in the liquid in the tank; and
a second lifting assembly comprising a second wafer carrier that is configured to:
engage the upper portion of the one or more semiconductor wafers after the upper portion of the one or more semiconductor wafers has been removed from the liquid; and
continue to raise the one or more semiconductor wafers until an entirety of the one or more semiconductor wafers is removed from the liquid in the tank.

2. The apparatus according to claim 1 wherein the tank has a longitudinal axis and wherein the second wafer carrier comprises a first carrier arm and a second carrier arm that are located on opposite sides of the longitudinal axis, wherein the second lifting assembly is operable to move the second wafer carrier from a second lowered position to a transfer position to a second raised position, wherein during movement of the second wafer carrier from the second lowered position to the transfer position the first and second carrier arms move inwardly towards one another to initiate contact between the first and second carrier arms and a portion of the upper portion of the one or more semiconductor wafers, and wherein during movement of the second wafer carrier from the transfer position to the second raised position the second wafer carrier supports the one or more semiconductor wafers and the first and second carrier arms move upwardly to lift the one or more semiconductor wafers entirely out of the liquid in the tank.

3. The apparatus according to claim 2 wherein the second lifting assembly comprises a first follower member that is operably coupled to the first carrier arm and a second follower member that is operably coupled to the second carrier arm, the first follower member moving along a first track and the second follower member moving along a second track as the second lifting assembly moves from the second lowered position to the transfer position to the second raised position.

4. The apparatus according to claim 3 wherein each of the first and second tracks comprise a bottom portion and a top portion, the bottom portions of each of the first and second tracks being oriented at an angle relative to the top portions of each of the first and second tracks so that as the first and second follower members move along the bottom portions of the first and second tracks, respectively, the first and second carrier arms of the second wafer carrier move towards one another.

5. The apparatus according to claim 1 wherein when the first wafer carrier is in the raised position, the second wafer carrier is movable from:
(1) a second lowered position whereby the second wafer carrier does not contact the one or more semiconductor wafers; to
(2) a transfer position whereby the second wafer carrier initiates contact with the one or more semiconductor wafers; to
(3) a second raised position; and
wherein during movement of the second wafer carrier from the transfer position to the second raised position the second wafer carrier takes over support of the one or more semiconductor wafers from the first wafer carrier and lifts the lower portion of the one or more semiconductor wafers out of the liquid in the tank.

6. The apparatus according to claim 1 further comprising a nozzle operably coupled to a source of isopropyl alcohol, wherein the nozzle is configured to inject a vapor of the isopropyl alcohol onto the liquid within the tank to create a surface tension differential at an interface between the liquid in the tank and the vapor of the isopropyl alcohol.

7. The apparatus according to claim 1 wherein the upper portion of the one or more semiconductor wafers that is not submerged in the liquid in the tank when the first wafer carrier is in the raised position comprises more than one-half of the one or more semiconductor wafers.

8. The apparatus according to claim 1 wherein the first wafer carrier remains fully submerged in the liquid in the tank in both the first lowered position and the first raised position, and wherein the second wafer carrier moves from a second lowered position to a second raised position during the raising of the one or more semiconductor wafers with the second wafer carrier, and wherein the second wafer carrier remains entirely outside of the liquid in the tank in both of the second lowered position and the second raised position.

9. The apparatus according to claim 1 wherein the second wafer carrier comprises a first carrier arm and a second carrier arm that are movable from a second lowered position to a second raised position, wherein when the second wafer carrier is in the second lowered position the first and second carrier arms are spaced apart by a gap having distance that is greater than a diameter of the one or more semiconductor wafers so that as the first wafer carrier transitions from the first lowered position to the first raised position the one or more semiconductor wafers pass through the gap between the first and second arms of the second wafer carrier.

10. The apparatus according to claim 9 wherein as the second wafer carrier transitions from the second lowered position to the second raised position the first and second carrier arms move inwardly towards one another until the first and second carrier arms contact the one or more semiconductor wafers and then the first and second carrier arms move upwardly away from the liquid in the tank while supporting the one or more semiconductor wafers to remove the lower portion of the one or more semiconductor wafers from the liquid in the tank.

11. A method of drying semiconductor wafers, the method comprising:
supporting one or more semiconductor wafers with a first wafer carrier at one or more contact points, wherein the one or more semiconductor wafers and the first wafer carrier are completely submerged in a liquid;
raising the first wafer carrier to begin lifting the one or more semiconductor wafers out of the liquid until an upper portion of the one or more semiconductor wafers is removed from the liquid and the one or more contact points remain submerged in the liquid;
engaging at least a portion of the upper portion of the one or more semiconductor wafers that has been removed from the liquid with a second wafer carrier; and
raising the second wafer carrier so that the second wafer carrier takes over support of the one or more semiconductor wafers, the second wafer carrier lifting the one or more semiconductor wafers until an entirety of the one or more semiconductor wafers is no longer submerged in the liquid.

12. The method according to claim 11 wherein the raising of the first wafer carrier comprises moving the first wafer carrier in a vertical direction.

13. The method according to claim 12 wherein the second wafer carrier comprising a first carrier arm and a second carrier arm, and wherein the engagement of the portion of the upper portion of the one or more semiconductor wafers with the second wafer carrier comprises moving the first and second carrier arms inwardly towards one another until the first and second carrier arms are in contact with the at least a portion of the upper portion of the one or more semiconductor wafers.

14. The method according to claim 13 wherein the raising of the second wafer carrier comprises moving the second wafer carrier in the vertical direction.

15. The method according to claim 11 wherein the first wafer carrier remains submerged in the liquid as the upper portions of the one or more semiconductor wafers are engaged by the second wafer carrier.

16. The method according to claim 11 wherein no portion of the second wafer carrier is submerged within the liquid in the tank at any point during the method.

17. The method according to claim 11 further comprising, while the one or more semiconductor wafers remain fully submerged in the liquid, forming a layer of a volatile organic compound on top of the liquid so that as the one or more semiconductor wafers are lifted out of the liquid the one or more semiconductor wafers pass through the layer of the volatile organic compound.

18. The method according to claim 11 wherein the raising of the first wafer carrier comprises raising the first wafer carrier from a first lowered position wherein the one or more semiconductor wafers are fully submerged in the liquid to a first raised position wherein the upper portions of the one or more semiconductor wafers are removed from the liquid.

19. The method according to claim 18 wherein when the first wafer carrier is in the first raised position, the second wafer carrier is movable from:
(1) a second lowered position whereby the second wafer carrier does not contact the one or more semiconductor wafers; to
(2) a transfer position whereby the second wafer carrier initiates contact with the one or more semiconductor wafers; to
(3) a second raised position; and
wherein during movement of the second wafer carrier from the transfer position to the second raised position the second wafer carrier takes over support of the one or more semiconductor wafers from the first wafer carrier and lifts a lower portion of the one or more semiconductor wafers out of the liquid in the tank.

20. The method according to claim 19 wherein moving the second wafer carrier from the second lowered position to the transfer position comprises moving two arm structures located on opposite sides of the one or more semiconductor wafers in a direction towards the one or more semiconductor wafers until the two arm structures come into contact with the one or more semiconductor wafers.
